(19) United States
(12) Patent Application Publication
(10) Pub. No.: US 2026/0362037 A1
(43) Pub. Date: Nov. 12, 2026

(54) ANALOG-TO-DIGITAL CONVERTER, METHOD OF OPERATING THE SAME AND IMAGE SENSOR INCLUDING ANALOG-TO-DIGITAL CONVERTER

(71) Applicant: Samsung Electronics Co., Ltd., Suwon-si (KR)

(72) Inventors: Yongjun CHO, Suwon-si (KR); Jaehong KIM, Suwon-si (KR); Daehwa PAIK, Suwon-si (KR); Seonju LEE, Suwon-si (KR); Seung Hyun LIM, Suwon-si (KR)

(73) Assignee: Samsung Electronics Co., Ltd., Suwon-si (KR)

(21) Appl. No.: 19/560,706

(22) Filed: Mar. 9, 2026

(30) Foreign Application Priority Data
May 12, 2025 (KR) 10-2025-0061422

(51) Int. Cl. H04N 25/78; H03M 1/12; H04N 25/60

(52) U.S. Cl. CPC H04N 25/78; H03M 1/12; H04N 25/60

(57) ABSTRACT

An analog-to-digital converter includes an input stage, an output stage, a switching circuit, a current source, a first multiplexer, and a second multiplexer. The input stage includes a first NMOS transistor configured to receive a pixel signal, a second NMOS transistor configured to receive a pixel signal, and a third NMOS transistor configured to receive a ramp signal. The output stage includes a first PMOS transistor and a second PMOS transistor connected in a current mirror structure. The switching circuit includes first to third switches configured to perform auto-zeroing. The current source is configured to provide a bias current at the input stage. The first multiplexer is configured to selectively connect one end of the first NMOS transistor to a power supply voltage, and the second multiplexer is configured to connect the one end of the second NMOS transistors to the power supply voltage.

### CROSS-REFERENCE TO RELATED APPLICATIONS

This application claims priority under 35 U.S.C. § 119 to Korean Patent Application No. 10-2025-0061422 filed on May 12, 2025, in the Korean Intellectual Property Office, the disclosure of which is incorporated by reference herein in its entirety.

### BACKGROUND

A Complementary Metal-Oxide Semiconductor (CMOS) image sensor includes pixels composed of CMOS transistors, and converts light energy into an electrical signal by using a photoelectric conversion element included in each pixel. The CMOS image sensor obtains information about a photographed image by using an electrical signal generated in each pixel.

In recent years, due to an increase in the number of pixels and a decrease in the pixel size, various pixel arrays and various processing techniques have been developed for optimizing and operating the image sensor in a high-illuminance environment and a low-illuminance environment. In order to increase the dynamic range, a technique for simultaneously performing a high conversion gain operation and a low conversion gain operation in one analog-to-digital converter has been developed.

However, when a low conversion gain operation and a high conversion gain operation are performed by one analog-to-digital converter, an unexpected problem such as random telegraph noise of an output image may occur. Therefore, correcting such image distortion has emerged as an important issue.

### SUMMARY

The inventive concepts relate to an analog-to-digital converter of an image sensor, and more particularly, to an analog-to-digital converter for removing random telegraph noise of an output image and an operating method thereof, and an image sensor including the analog-to-digital converter.

Some example embodiments of the inventive concepts provide a device and method for providing a high dynamic range (HDR) image by performing a dual conversion gain operation by one analog-to-digital converter.

Some example embodiments of the inventive concepts provide a device and a method for removing random telegraph noise that may occur when performing a dual conversion gain operation by one analog-to-digital converter.

According to some example embodiments, an analog-to-digital converter includes an input stage including a first NMOS transistor configured to receive a pixel signal through a first capacitor, a second NMOS transistor configured to receive the pixel signal through a second capacitor, and a third NMOS transistor configured to receive a ramp signal through a third capacitor, an output stage including a first PMOS transistor and a second PMOS transistor connected by a current mirror structure, the first PMOS transistor configured to mirror a current flowing through the first NMOS transistor and to transmit the current to the second PMOS transistor, a switching circuit including a first switch between a first node and an output node of the output stage, the first node being between the first capacitor and the first NMOS transistor, a second switch between a second node and the output node of the output stage, the second node being between the second capacitor and the second NMOS transistor, and a third switch between a third node and a fourth node, the third node being between the third capacitor and the third NMOS transistor, and the fourth node being between the first PMOS transistor and the second PMOS transistor, a current source configured to provide a bias current to the input stage, a first multiplexer configured to connect a first end of the first NMOS transistor to the output node of the output stage or to a power supply voltage, and a second multiplexer configured to connect a first end of the second NMOS transistor to the output node of the output stage or to the power supply voltage.

According to some example embodiments, an analog-to-digital converter includes a first PMOS transistor and a second PMOS transistor connected by a current mirror structure, a first end of the first PMOS transistor being connected to a first end of the second PMOS transistor by a power supply voltage, a low conversion gain branch including a first NMOS transistor configured to receive a pixel signal through a first capacitor, and a first multiplexer configured to connect the first end of the first NMOS transistor to the second end of the second PMOS transistor or to the power supply voltage, a high conversion gain branch including a second NMOS transistor configured to receive the pixel signal through a second capacitor, and a second multiplexer configured to connect the first end of the second NMOS transistor to the second end of the second PMOS transistor or to the power supply voltage, a reference branch including a third NMOS transistor configured to receive a ramp signal through a third capacitor, and a current source connected to the low conversion gain branch, the high conversion gain branch, and the reference branch.

According to some example embodiments, an image sensor includes a pixel array including a plurality of pixel groups, a first pixel group of the plurality of pixel groups including a first plurality of pixels sharing a first floating diffusion node, and an analog-to-digital converter configured to process a pixel signal output from the first plurality of pixels, the analog-to-digital converter including an input stage including a first NMOS transistor configured to receive the pixel signal through a first capacitor, a second NMOS transistor configured to receive the pixel signal though a second capacitor, and a third NMOS transistor configured to receive a ramp signal through a third capacitor, an output stage including a first PMOS transistor and a second PMOS transistor connected by a current mirror structure, a current source configured to provide a bias current to the input stage, a first multiplexer configured to connect the first end of the first NMOS transistor to an output node of the output stage or to a power supply voltage, and a second multiplexer configured to connect the first end of the second NMOS transistor to the output node of the output stage or to the power supply voltage.

### BRIEF DESCRIPTION OF DRAWINGS

The above and other objects and features will be more apparent from the following description of some example embodiments, taken in conjunction with the accompanying drawings, in which:

FIG. 1 illustrates an example configuration of an image sensor according to some example embodiments of the inventive concepts.

FIG. 2 is a circuit diagram illustrating an example configuration of the pixel group of FIG. 1.

FIG. 3 is a circuit diagram illustrating a floating diffusion node when the dual conversion gain transistor is turned off.

FIG. 4 is a circuit diagram illustrating a floating diffusion node when the dual conversion gain transistor is turned on.

FIG. 5 is a circuit diagram illustrating an example configuration of the pixel group of FIG. 1.

FIG. 6 shows a top view of the pixel array of FIG. 1.

FIG. 7 shows a top view of the pixel array of FIG. 1.

FIG. 8 shows a top view of the pixel array of FIG. 1.

FIG. 9 is an example circuit diagram of the comparator shown in FIG. 1.

FIG. 10 illustrates the operation of a comparator when there is no configuration to provide a power supply voltage via a multiplexer.

FIGS. 11A and 11B illustrate an example configuration of the multiplexer shown in FIG. 9.

FIG. 12 is a timing diagram related to the operation of the comparator of FIG. 1.

FIG. 13 illustrates operation of a comparator associated with auto-zeroing performed prior to a low conversion gain operation.

FIG. 14 illustrates the operation of a comparator associated with outputting a low conversion gain reset signal.

FIG. 15 shows the operation of the comparator associated with auto-zeroing performed after the output of the low conversion gain reset signal.

FIG. 16 shows the operation of the comparator associated with the output of the high conversion gain reset signal and the output of a high conversion gain image signal.

FIG. 17 illustrates the operation of a comparator associated with a low conversion gain image signal.

FIG. 18 shows a top view of the pixel array of FIG. 1.

FIG. 19 shows a top view of the pixel array of FIG. 1.

FIG. 20 is a timing diagram related to the operation of the comparator of FIG. 1.

FIG. 21 is a flowchart illustrating a method of operating an analog-to-digital converter according to some example embodiments of the inventive concepts.

### DETAILED DESCRIPTION

Below, some example embodiments of the inventive concepts will be described in detail and clearly to such an extent that an ordinary one in the art easily carries out the present disclosure.

The components described with reference to the terms “unit”, “module”, “block”, “stage”, “or”, “er”, and the like used in the detailed description and the functional blocks illustrated in the drawings may be implemented in the form of software, hardware, or a combination thereof. Illustratively, the software may be machine code, firmware, embedded code, and/or application software. For example, the hardware may include an electrical circuit, an electronic circuit, a processor, a computer, an integrated circuit, integrated circuit cores, a pressure sensor, an inertial sensor, a microelectromechanical system (MEMS), a passive element, or a combination thereof.

As used herein, including in the claims, “or” as used in a list of items (e.g., a list of items prefaced by a phased such as “at least one of” or “one or more of” or “one or both of” indicates as inclusive list such that, for example, a list of at least one of A, B, or C means A or B or C or AB or AC or BC or ABC (i.e., A and B and C).

When the words “about” and “substantially” are used in this application in connection with a numerical value, it is intended that the associated numerical value include a tolerance of ±10% around the stated numerical value, unless otherwise explicitly defined. Further, regardless of whether numerical values are modified as “about” or “substantially,” it will be understood that these values should be construed as including a of ±10% around the stated numerical value.

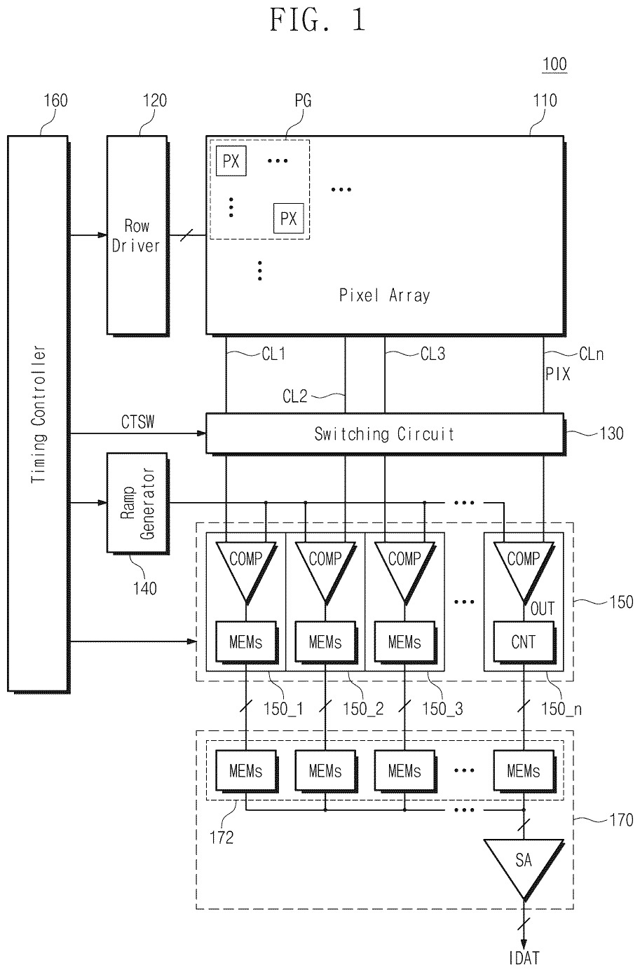

FIG. 1 illustrates an example configuration of an image sensor according to some example embodiments of the inventive concepts.

The image sensor 100 may include a pixel array 110, a row driver 120, a switching circuit 130, a ramp signal generator 140, an analog-to-digital converting block (hereinafter referred to as an ADC block 150), a timing controller 160, and/or a buffer 170.

The pixel array 110 may include a plurality of pixels arranged in a matrix along rows and/or columns. Each, or one or more, of the plurality of pixels may include a photoelectric conversion element. For example, the photoelectric conversion element may include a photodiode, a phototransistor, a photogate, a pinned photodiode, and/or the like. Each, or one or more, of the plurality of pixels may sense light using a photoelectric conversion element and convert the sensed light into an electrical signal (hereinafter, a pixel signal).

The pixel array 110 may include a plurality of pixel groups PG, each, or one or more, of which includes a plurality of pixels PX. Each, or one or more, pixel group PG may include at least two or more pixels. As an example, the pixel group PG may include nine pixels PX arranged in three rows and three columns, or may include four pixels PX arranged in two rows and two columns, but the number of pixels included in the pixel group PG is not limited thereto.

The pixels included in the pixel group PG may share at least one or more floating diffusion regions. For example, pixels included in the pixel group PG may share one floating diffusion region. In this case, pixels of each, or one or more, pixel group PG may be commonly connected to one column line (e.g., CL1). Alternatively, pixels included in the pixel group PG may share a plurality of floating diffusion regions. For example, pixels in one column of the pixel group PG may share one floating diffusion region, pixels in two columns may share another floating diffusion region, and pixels in three columns may share yet another floating diffusion region. In this case, the pixels in a first column of the pixel group PG shown in the figure may be commonly connected to a column line CL1, the pixels in a second column may be commonly connected with the column line CL2, and the pixels in a third column may be common connected with a column line CL3.

The pixel group PG may include the same type of pixels for outputting information related to the same color. For example, the pixel group PG may include a red pixel R that converts light in the red spectral region into an electrical signal, green pixels Gr and Gb that convert light in the green spectral region into the electrical signal, or blue pixels B that convert light in a blue spectral region into electrical signals. To this end, a plurality of color filters may be formed on the pixel groups PG to form a multi-color filter array (Multi-CFA).

Each, or one or more, pixel included in the pixel group PG may include a plurality of transistors controlled by the row driver 120. Alternatively, in some example embodiments, two or more pixels adjacent to each other may form one pixel group, and the two or more pixels included in one pixel group may share at least some of a transfer transistor, a source follower transistor, a selection transistor, and/or a reset transistor with each other.

Pixel groups arranged along one column may be alternately connected to two column lines. For example, some of the pixel groups arranged in the first column may be connected to the first column line CL1, and others may be connected to the second column line CL2. Similarly, some of the pixel groups arranged in the second column may be connected to the third column line CL3, and others may be connected to the fourth column line CL4.

The row driver 120 may select and drive a row of the pixel array 110. The row driver 120 may decode the address and/or control signal generated by the timing controller 160 to generate control signals for selecting and driving a row of the pixel array 110. For example, it may include control signals, a signal for selecting a pixel, a signal for resetting a floating diffusion node, a signal for choosing a column line, etc.

The switching circuit 130 may control a path through which an analog signal (e.g., a pixel signal) output from the pixel array 110 is transferred to the ADC block 150. In a first mode (e.g., a normal mode), the switching circuit 130 may set a path such that one pixel group PG is connected to one analog-to-digital converter (hereinafter, referred to as an ADC). In the second mode (e.g., a HDR mode), the switching circuit 130 may set a path such that one pixel group PG is connected to two ADCs. As a result, a high conversion gain operation may be processed by one ADC, and a low conversion gain operation may also be processed by the other ADC. For example, the switching circuit 130 may include a plurality of switches that operate under the control of the switch control signal CTSW generated by the timing controller 160. The switch referred to herein below may be implemented as NMOS transistor, PMOS transistor, transmission gate, combinations thereof, or the like.

Alternatively, in the HDR mode, the switching circuit 130 may set a path such that one pixel group PG is connected to one ADC converter. In this case, one ADC converter may simultaneously perform a low conversion gain operation and a high conversion gain operation on the signal output from the pixel group PG. In this case, the number of column lines required, or sufficient, may be increased, but since one ADC simultaneously performs an operation related to the low conversion gain and an operation related to a high conversion gain, the operation speed may be doubled. Furthermore, by acquiring an image by using the image signal acquired by the high conversion gain operation and the image signal obtained by the low conversion gain, a dynamic range of the image can be improved.

The ramp signal generator 140 may generate a ramp signal. The ramp signal generator 140 may operate under the control of the timing controller 160. For example, the ramp signal generator 140 may operate under a control signal, such as a ramp enable signal, a mode signal, or the like. When the ramp enable signal is activated, the ramp signal generator 140 may generate a ramp signal having a slope set based on the mode signal.

The ADC block 150 may convert an analog signal (e.g., the pixel signal PIX) output from the pixel array 110 into a digital signal. As an example, the ADC block 150 may include a plurality of ADCs 150_1 to 150_n, and each, or one or more, ADC may include a comparator COMP and a counter CNT. The comparator COMP may compare the pixel signal output through a column line (e.g., any one of CL1 to CLn) connected to the comparator COMP and the ramp signal RAMP, and may output a comparison result. The comparator COMP may operate based on a correlated-double sampling (hereinafter referred to as CDS) technique that obtains a reset signal and an image signal for a pixel signal, and extracts the difference into valid signal components. The comparator COMP may be referred to as a CDS circuit because it operates based on correlated double sampling.

The counter CNT may count pulses of an output signal of a corresponding comparator COMP. The counter CNT may operate under the control of the timing controller 160. For example, the counter CNT may operate under control signals such as a counter clock signal, a counter reset signal that controls a reset of the counter CNT, an inversion signal that inverts an internal bit of the counter CNT, and/or the like. The counter CNT may count a comparison result signal according to the counter clock signal and output the comparison result signal as a digital signal.

The counter CNT may include an up/down counter, a bit-wise inversion counter, and/or the like. The bit-wise inversion counter may perform an operation similar to an up/down counter. For example, a bit-wise inversion counter may perform a function of only performing an up count and a function of inverting all bits inside the counter to make a 1's complement when a specific signal is received. The bit-wise inversion counter may perform a reset count and then invert it to convert to a complement of 1, that is, a negative value.

The timing controller 160 may generate a control signal and/or a clock for controlling the operation and/or timing of each of the row driver 120, the switching circuit 130, the ramp signal generator 140, the ADC block 150, and/or the counter CNT.

The buffer 170 may include a set 172 of memories MEMs and/or a sense amplifier SA. The memories MEMs may store a digital signal output from a corresponding ADC. The sense amplifier SA may sense and amplify the stored digital signal. The sense amplifier SA may output the amplified digital signal as image data IDAT. For example, the image data IDAT may include information about a color of an object and information about a phase of the object.

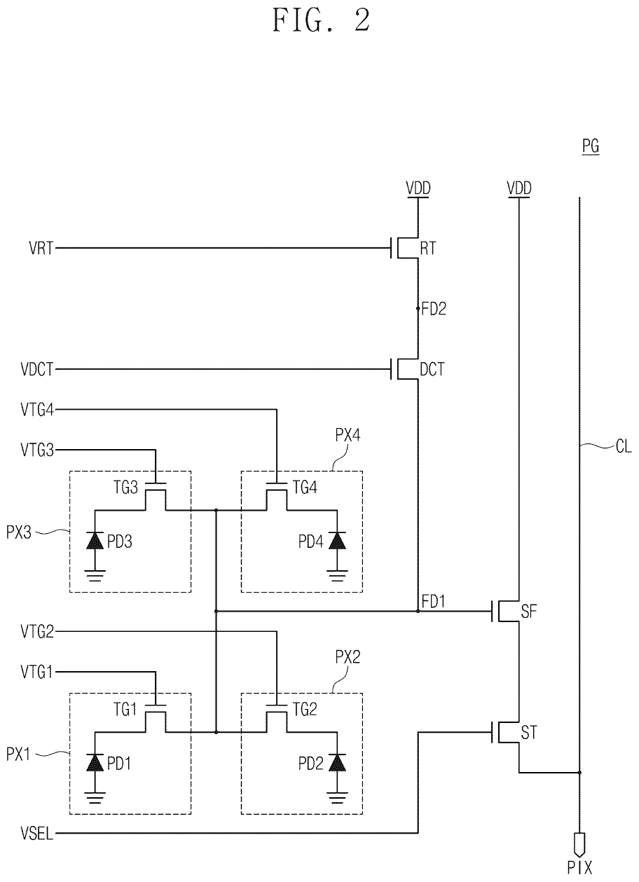

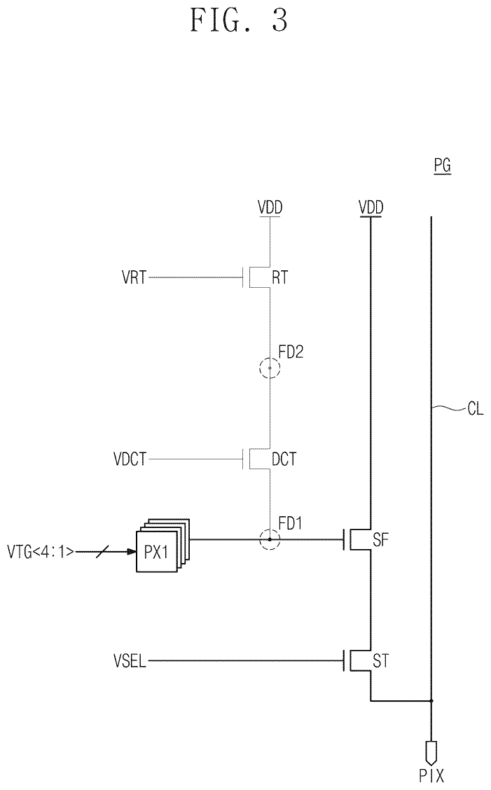

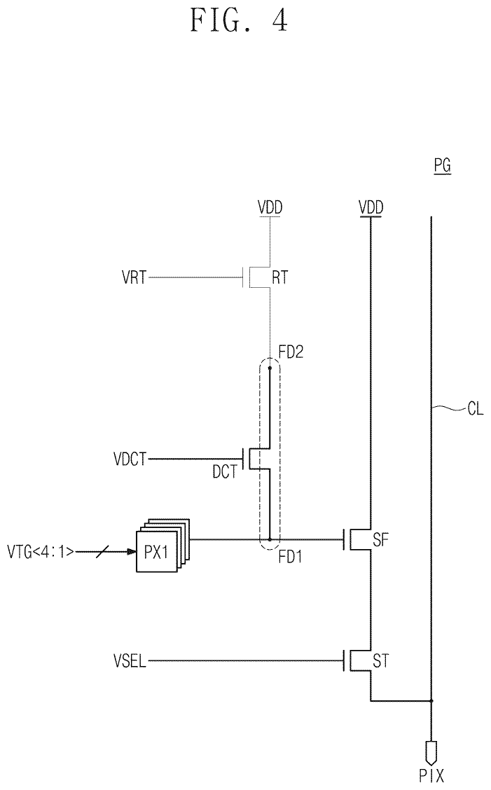

FIG. 2 is a circuit diagram illustrating an example configuration of the pixel group PG of FIG. 1. FIG. 3 is a circuit diagram illustrating a floating diffusion node when the dual conversion gain transistor DCT is turned off. FIG. 4 is a circuit diagram illustrating a floating diffusion node when the dual conversion gain transistor DCT is turned on.

First, referring to FIG. 2, the pixel group PG may include photoelectric conversion elements PD1 to PD4, transfer transistors TG1 to TG4, a dual conversion gain transistor DCT, a reset transistor RT, a source follower transistor SF, and/or a selection transistor ST. The first pixel PX1 may include a first photoelectric conversion element PD1 and/or a first transfer transistor TG1, and other pixels PX2 to PX4 may include similar components. Although each pixel is illustrated as including only the photoelectric conversion element and the transfer transistor in the figure, it may be understood that each, or one or more, pixel further includes a dual conversion gain transistor DCT, a reset transistor RT, a source follower transistor SF, and/or a selection transistor ST. For example, each, or one or more, of the first to fourth pixels PX1 to PX4 may share a dual conversion gain transistor DCT, a reset transistor RT, a source follower transistor SF, and/or a selection transistor ST.

The first floating diffusion node FD1 may have a capacitance CFD1, and the second floating diffusion node FD2 may have a capacitance CFD2. The capacitance CFD1 may be capacitance by a parasitic capacitor of the first floating diffusion node FD1, and the capacitance CFD2 may be capacitance by the parasitic capacitors of the second floating diffusion node FD2. Therefore, when the dual conversion gain transistor DCT is turned on, the first floating diffusion node FD1 may be connected to the second floating diffusion node Fd2, and the floating diffusion node FD1 or FD2 may have a capacitance corresponding to the sum of the capacitance CFD1 and the capacitance CFD2. However, the inventive concepts are not limited thereto, and a separate physical MIM (Metal Insulator Metal) capacitor or a DRAM capacitor may be connected to the floating diffusion nodes FD1 and/or FD2.

The transfer transistors TG1 to TG4 may transfer charges generated by the photoelectric conversion elements PD1 to PD4 to the first floating diffusion node FD1 or the second floating diffusion node FD2. For example, one end of the transfer transistors TG1, TG2, TG3, and TG4 may be connected to the photoelectric conversion elements PD1, PD2, PD3, and PD4, respectively, and the other ends may be commonly connected to the first floating diffusion node FD1. The transfer transistors TG1, TG2, TG3, and TG4 may be controlled by the transfer signals VTG1, VTG2, VTG3, and VTG4 received from the row driver (FIGS. 1, 120), respectively.

The first floating diffusion node FD1 or the second floating diffusion node FD2 may accumulate charges corresponding to an incident amount of light. During a time when the transfer transistors TG1, TG2, TG3, and TG4 are respectively turned on by the transfer signals VTG1, VTG2, VTG3, and VTG4, charges provided from the photoelectric conversion elements PD1, PD2, PD3, and PD4 may be accumulated in the first floating diffusion node FD1 or the second floating diffusion node FD2. The first floating diffusion node FD1 may be connected to a gate electrode of the source follower transistor SF that is driven as a source follower amplifier. As a result, a voltage potential corresponding to the charge accumulated in the first floating diffusion node FD1 or the second floating diffusion node FD2 may be formed.

In some example embodiments, when the intensity of light is strong, the capacitance (e.g., CFD1) of the first floating diffusion node FD1 may not be sufficient to accommodate the charges generated by the photoelectric conversion elements PD1 to PD4. In this case, since the first floating diffusion node FD1 is easily saturated, information of an image to be captured may not be properly generated. Thus, to reduce, or prevent, saturation, the capacitance (e.g., CFD2) of the second floating diffusion node FD2 may be used. When the dual conversion gain transistor DCT is turned on by the gate voltage (e.g., VDCT in FIG. 4), the capacitance of the floating diffusion node FD1 or FD2 may increase by the sum of the capacitance CFD1 and the capacitance CFD2.

According to some example embodiments, the exposure time of each, or one or more, pixel constituting the pixel group PG is kept equal to each other, but the dynamic range of the image can be expanded by changing the conversion gain using the dual conversion gain transistor DCT and/or the capacitance CFD2 of the second floating diffusion node. In addition, a motion artifact that often occurs when exposure times of pixels are made different from each other can be reduced, or prevented.

The reset transistor RT may be turned on by the reset signal VRST to provide a reset voltage (e.g., a power supply voltage VDD) to the first floating diffusion node FD1 and/or the second floating diffusion node FD2. As a result, the electric charges accumulated in the first floating diffusion node FD1 and/or the second floating diffusion node FD2 moves to the power supply voltage VDD node, and the voltage of the first floating diffusion nodes FD1 and/or second floating diffusion nodes FD2 may be reset.

The source follower transistor SF may amplify a change in the electrical potential of the first floating diffusion node FD1 and/or the second floating diffusion node FD2 and generate a voltage (e.g., the pixel signal PIX) corresponding thereto. The selection transistor ST may be driven by the selection signal VSEL to select a pixel to be read in a row unit (that is, row by row). When the selection transistor ST is turned on, the pixel signal PIX may be output through the column line CL.

In some example embodiments, the number of pixels included in one pixel group PG, the number of floating diffusion nodes FD, the arrangement of color filters, and the like are not limited thereto. For example, in some example embodiments, the pixel group PG may include nine pixels and three floating diffusion nodes, in which case the three pixels may share one floating diffusion node.

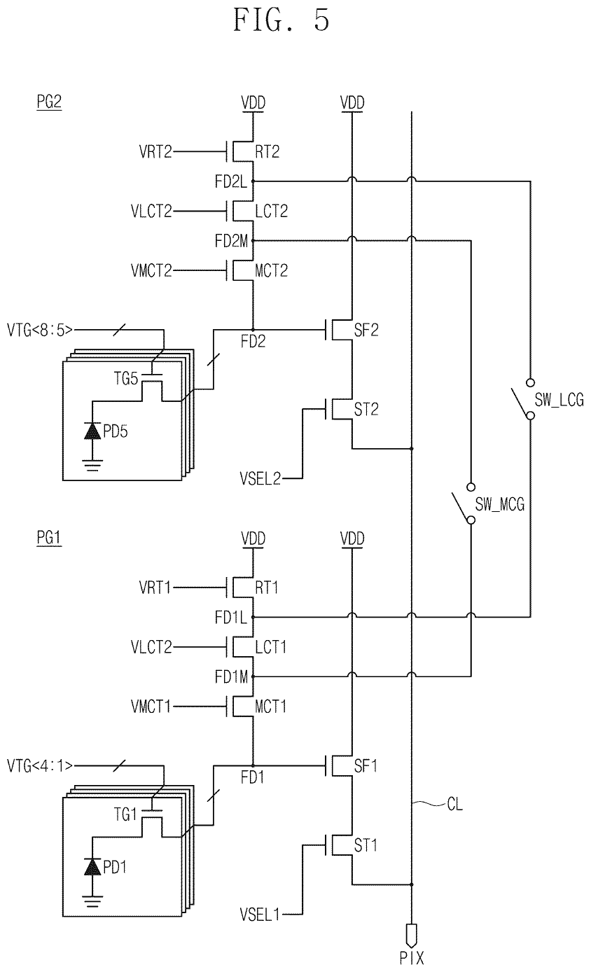

FIG. 5 is a circuit diagram illustrating an example configuration of the pixel group PG of FIG. 1.

Referring to FIG. 5, the first pixel group PG1 may include photoelectric conversion elements PD1 to PD4, transfer transistors TG1 to TG4, a first middle conversion gain transistor MCT1, a first low conversion gain transistor LCT1, a first reset transistor RT1, a first source follower transistor SF1, and/or a first selection transistor ST1. The second pixel group PG2 may include photoelectric conversion elements PD5 to PD8, transfer transistors TG5 to TG8, a second middle conversion gain transistor MCT2, a second low conversion gain transistor LCT2, a second reset transistor RT2, a second source follower transistor SF2, and/or a second selection transistor ST2.

The structure of the pixel groups PG1, PG2 may be generally similar to the pixel group described with reference to FIG. 2. However, the first reset transistor RT1, the first low conversion gain transistor LCT1, and/or the first middle conversion gain transistor MCT1 may be connected in series, and/or the second reset transistor RT2, the second low conversion gain transistor LCT2, and/or the second middle conversion gain transistor MCT2 may be connected in series. The node FD1M and the node FD2M may be connected by the switch SW_MCG, and the node FD1L and the node FD2L may be connected by a switch SW_LCG. One end of the first selection transistor ST1 and one end of the second selection transistor ST2 may be connected to the column line CL. However, in some example embodiments, one end of the first selection transistor ST1 and one end of the second selection transistor ST2 may be respectively connected to different column lines.

In some example embodiments, according to an on/off operation of the transistors MCT1, MCT2, LCT1, and LCT2, an operation for obtaining conversion gains of various values may be performed. For example, when the transistors MCT1 and MCT2 are turned on and the floating diffusion nodes FD1M and FD2M are connected by using the switch SW_MCG, a capacitance higher than the capacitance of the floating diffusion node FD1 and FD2 in FIG. 2 may be obtained. Further, when the transistors MCT1, MCT2, LCT1, and LCT2 are turned on and the floating diffusion nodes FD1M and FD2M are connected by using the switch SW_MCG and/or the floating diffusion nodes FD1L and FD2L are connected by using a switch SW_LCG, a higher value of capacitance may be obtained.

However, obtaining conversion gains of various values is not limited to those described above. For example, by appropriately turning on/off the transistors MCT1, MCT2, LCT1, and LCT2 and the switches SW_MCG and SW_LCG, operations for obtaining conversion gains of various values may be performed.

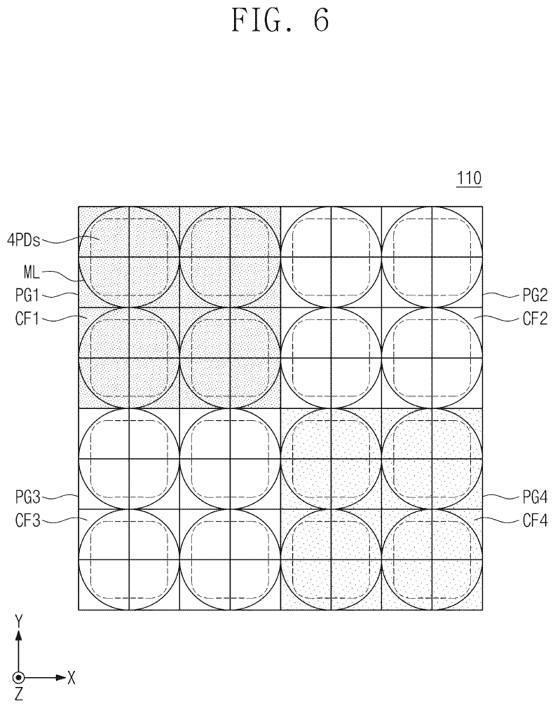

FIG. 6 shows a top view of the pixel array 110 of FIG. 1.

The pixel array 110 may include a plurality of pixel groups PG1 to PG4. The pixel groups PG1 to PG4 may be repeatedly formed along the X-axis and the Y-axis, and may be arranged in a Bayer pattern. Each, or one or more, of the pixel groups PG1 to PG4 may include 4×4 pixels arranged along the X-axis and the Y-axis. Each, or one or more, pixel may include a photoelectric conversion element PD. Color filters CF1 to CF4 for transmitting light of a specific wavelength band may be formed on the pixel groups PG1 to PG4, respectively. For example, the first color filter CF1 may transmit red light, the second color filter CF2 and/or the third color filter CF3 may transmit green light, and/or the fourth color filter CF4 may transmit blue light.

A microlens ML may be formed on a color filter formed on each, or one or more, pixel. For example, one microlens ML may correspond to four pixels (or four photoelectric conversion elements, 4PDs), and four microlenses may be provided on the color filter CF1. In this case, auto-focusing may be performed by turning on the transfer transistors corresponding to half of the four pixels (e.g., the left two pixels) corresponding to one microlens to output a first pixel signal, turning on all the transfer transistors corresponds to the four pixels corresponding to one micro lens to output a second pixel signal, and comparing the first pixel signal and the second pixel signal. That is, with the pixel array of FIG. 6, auto-focusing can be performed on all, or one or more, pixels.

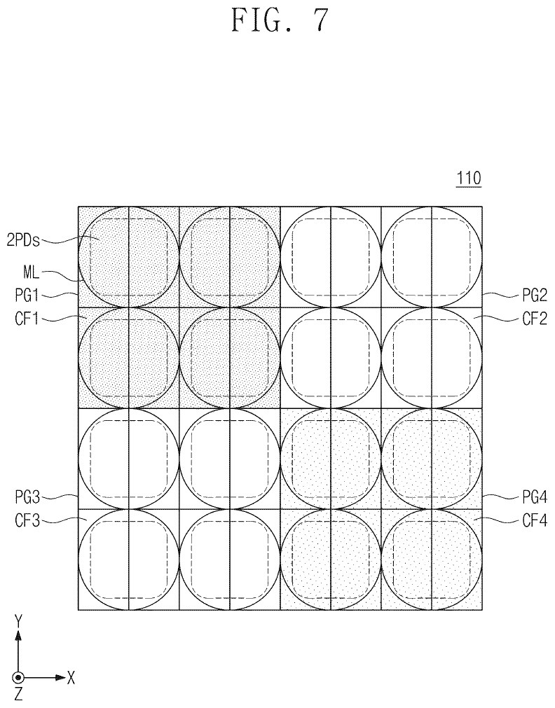

FIG. 7 shows a top view of the pixel array 110 of FIG. 1. The structure of the pixel array of FIG. 7 may be partially similar to that of the pixel array in FIG. 6, and redundant descriptions will be omitted.

The pixel array 110 may include a plurality of pixel groups PG1 to PG4. The pixel groups PG1 to PG4 may be repeatedly formed along the X-axis and the Y-axis, and may be arranged in a Bayer pattern. Each, or one or more, of the pixel groups PG1 to PG4 may include 2×2 pixels arranged along the X-axis and the Y-axis. Each, or one or more, pixel may include two photoelectric conversion elements 2PDs, and one microlens ML may be provided on each, or one or more, pixel. For example, the pixel array 110 may include a back-side deep trench isolation (BDTI) structure.

Auto-focusing may be performed by turning on a transfer transistor corresponding to one of two photoelectric conversion elements (e.g., PD on the left side) corresponding to one microlens to output a first pixel signal, turning on all transfer transistors corresponding to the two photoelectric conversion elements corresponding to one micro lens to output a second pixel signal, and comparing the first pixel signal and the second pixel signal. That is, with the pixel array of FIG. 7, auto-focusing can be performed on all, or one or more, pixels.

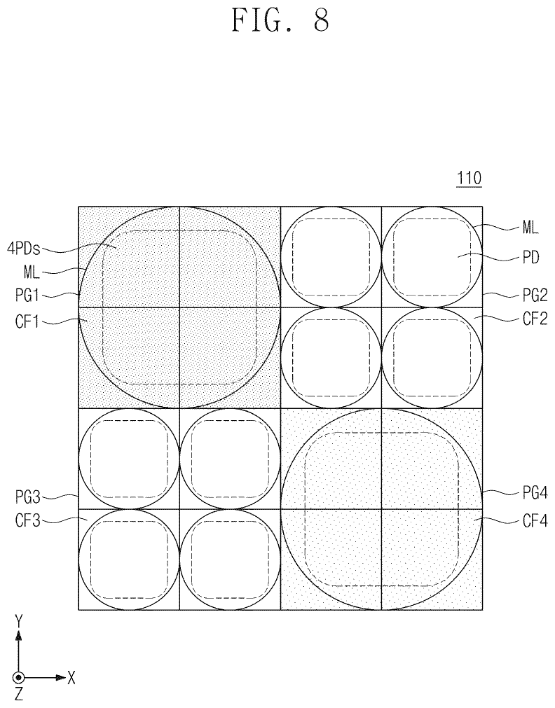

FIG. 8 shows a top view of the pixel array 110 of FIG. 1.

The pixel array 110 may include pixel groups PG1 to PG4. The arrangement of the pixels, the arrangement of the color filters, whether the pixels belonging to each pixel group share the photoelectric conversion element, and the like are generally similar to those described above in FIG. 6 or FIG. 7.

However, in the case of the pixel group PG1 related to red light and the pixel group PG4 related to blue light, one microlens ML may be disposed on four pixels. Pixels of pixel group PG1 and pixels of pixel group PG4 may be used for auto-focusing as well as acquisition of an image signal. For example, after acquiring an image from some of the four pixels (e.g., two pixels on left, two pixels on right, two pixels on top, two pixels on bottom, etc.), and acquiring an image from the four pixels, auto-focusing may be performed using the difference between the two image signals.

On the other hand, one microlens ML may be disposed on each, or one or more, pixel of the pixel groups PG2 and PG3 associated with green light. Pixels of the pixel groups PG2 and PG3 are not involved in auto-focus, and may only be involved in the output of the image signal. However, the inventive concepts are not limited thereto.

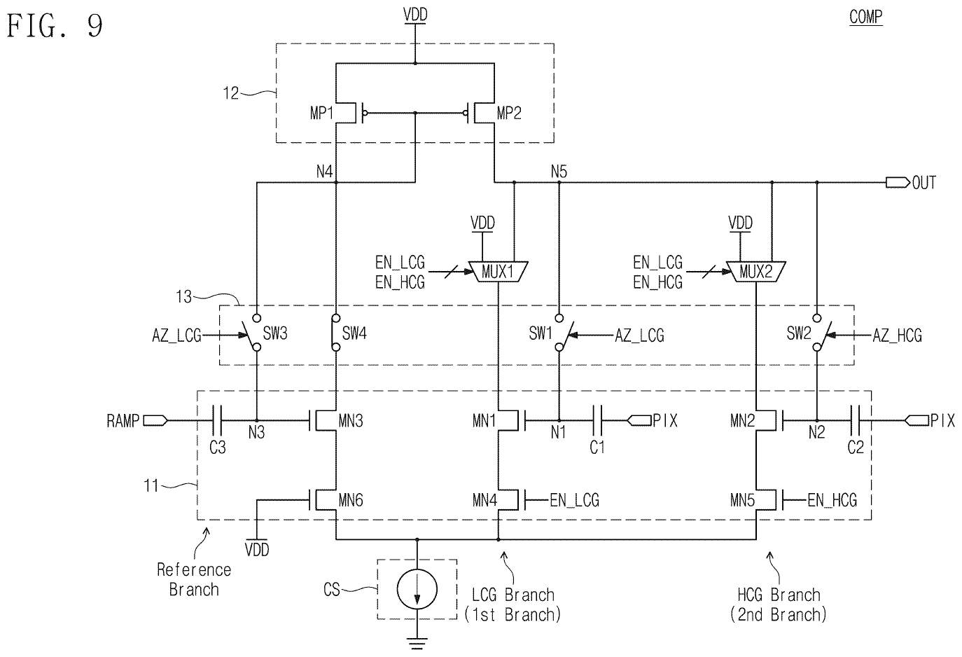

FIG. 9 is an example circuit diagram of the comparator COMP shown in FIG. 1.

The comparator COMP may be implemented as an OTA (Operational Transconductance Amplifier). The comparator COMP may include an input stage 11, an output stage 12, a switching circuit 13, a current source CS, and/or multiplexers MUX1 and/or MUX2.

The input stage 11 may include a first NMOS transistor MN1 and/or a second NMOS transistor MN2 that receive the pixel signal PIX, and/or a third NMOS transistor MN3 that receives the ramp signal RAMP. A first capacitor C1 for storing the pixel signal PIX may be connected to the gate electrode of the first NMOS transistor MN1, and a second capacitor C2 for storing the pixel signals PIX may be connected to the gate electrode of the second NMOS transistors MN2. The pixel signals PIX stored in the first capacitor C1 and/or the second capacitor C2 may be used for a high conversion gain operation and/or a low conversion gain operation, respectively. A third capacitor C3 for storing the ramp signal RAMP may be connected to the gate electrode of the third NMOS transistor MN3.

The input stage 11 may include NMOS transistors MN4 and/or MN5 activated by the enable signals EN_LCG and/or EN_HCG, respectively. For example, in the low conversion gain operation, the fourth NMOS transistor MN4 may be activated by the enable signal EN_LCG, and the fifth NMOS transistor MN5 may be deactivated. Then, in the high conversion gain operation, the fifth NMOS transistor MN5 may be activated by the enable signal EN_HCG, and the fourth NMOS transistor MN4 may be deactivated.

In some example embodiments, the input stage 11 may include a sixth NMOS transistor MN6 that is always turned on by the power supply voltage VDD for symmetry required, or sufficient, in the OTA. For example, a resistance value of the sixth NMOS transistor MN6 may be substantially the same as a resistance value of each, or one or more, of the fourth NMOS transistors MN4 and/or the fifth NMOS transistor MN5. However, the sixth NMOS transistor MN6 is not limited thereto, and may be replaced with various elements such as a resistor, a PMOS transistor, a transmission gate, and/or the like, or omitted.

The input stage 11 may generate a current corresponding to a difference between the differential inputs (e.g., RAMP, PIX). For example, in the low conversion gain operation, a current corresponding to a level difference between the ramp signal RAMP and the pixel signal PIX input to the first NMOS transistor MN1 may flow to the first NMOS transistor MN1. Then, in the high-conversion gain operation, a current corresponding to a level difference between the ramp signal RAMP and the pixel signal PIX input to the second NMOS transistor MN2 may flow through the second NMOS transistor MN2.

The output stage 12 may be implemented with a current mirror structure, and may generate an output voltage OUT whose level is determined according to current mirroring. The output voltage OUT may be used as a comparison result for digital conversion. In some example embodiments, the output stage 12 may include PMOS transistors MP1 and/or MP2. For example, the first PMOS transistor MP1 may mirror a current flowing through the first NMOS transistor MN1 and transmit the current to the second PMOS transistor MP2.

The switching circuit 13 may include switches SW1, SW2, and/or SW3. The first switch SW1 and/or the third switch SW3 may be switched on by the auto zero signal AZ_LCG before starting of the low conversion gain operation to connect the nodes N3 and N4 to each other, and may connect the nodes N1 and N5 to each other. As a result, the comparator COMP may be initialized such that the offset is reduced, or removed. The second switch SW2 may be switched on by the auto zero signal AZ_HCG before staring of the high conversion gain operation to connect the nodes N2 and N5 to each other. As a result, the comparator COMP may be initialized such that the offset is reduced, or removed.

In some example embodiments, the switching circuit may include a switch SW4 that is always switched on for symmetry required, or sufficient, in the OTA. The resistance value of the switch SW4 may be substantially the same as the resistance value of the multiplexer MUX1 and/or the multiplexer muX2. For example, the switch SW4 may be implemented as an element such as a resistor, an NMOS transistor, a PMOS transistor, a transmission gate, or the like, or omitted.

The current source CS may provide a bypass current to maintain the operation of the transistors constituting the comparator COMP.

In some example embodiments, the NMOS transistors MN1 and/or MN4, the first capacitor C1, the first multiplexer MUX1, and/or the switch SW1 involved in the low conversion gain operation may be referred to as an LCG branch (or a first branch), and the NMOS transistors MN2 and/or MN5, the second capacitor C2, the second multiplexer MUx2, and/or the switch SW2 involved in the high conversion gain operation may also be referred to as a HCG branch (or the second branch). The NMOS transistors MN3 and/or MN6, the third capacitor C3, and/or the switches SW3 and SW4 may be referred to as reference branches (or third branches).

The multiplexers MUX1 and/or MUX2 may connect one end of the NMOS transistors MN1 and/or MN2 to the power supply voltage VDD or the output node N5 in response to the enable signals EN_LCG and/or EN_HCG. For example, the first multiplexer MUX1 may connect the first NMOS transistor MN1 to the output node N5 during a low conversion gain operation, and may connect the first NMOS transistor MN1 to the power supply voltage VDD during a high conversion gain operation. The second multiplexer MUX2 may connect the second NMOS transistor MN2 to the node N5 during the high conversion gain operation, and may connect the second NMOS transistor MN2 to the power supply voltage VDD during the low conversion gain operation.

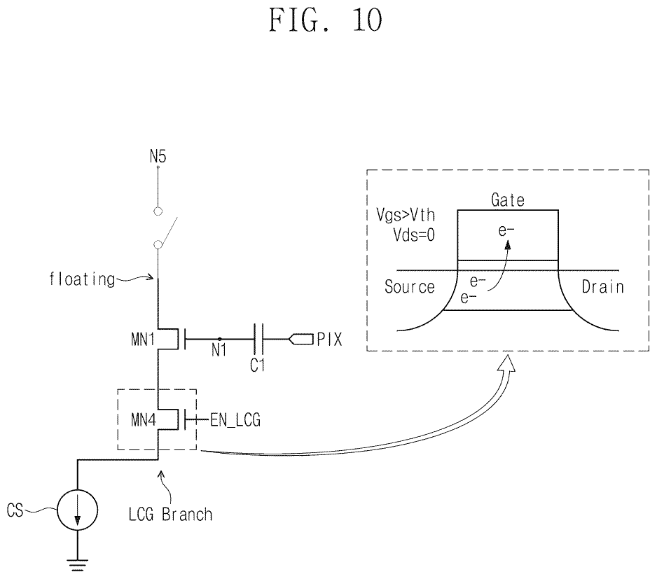

FIG. 10 illustrates the operation of a comparator when there is no configuration to provide a power supply voltage through a multiplexer.

It is assumed that there is no configuration in which the first multiplexer MUX1 connects the power supply voltage VDD to one end of the first NMOS transistor MN1 in the circuit diagram of FIG. 9. This configuration is illustratively shown in FIG. 10, with only the LCG branch of the comparator configurations being shown for simplicity of illustration.

It is further assumed that a channel is formed in the first NMOS transistor MN1 in the previous frame, and thus a low conversion gain operation is performed in the LCG branch. When the connection between the first NMOS transistor MN1 and the node N5 is cut off in a state where a channel is formed in the first NMOS transistor MN1, the drain electrode of the first NMOS transistor MN1 is in a floating state. Since the source electrode of the first NMOS transistor MN1 is still connected to the current source CS, the gate-source voltage Vgs of the first NMOS transistor MN1 may still be greater than the threshold voltage Vth. Therefore, the channel of the first NMOS transistor MN1 may be maintained without being extinguished.

At this time, some of the charges of the channel may be diffused to the interface of the first NMOS transistor MN1 to be trapped, which may change the level of the threshold voltage of the first NMOS transistor MN1. In order for the trapped charge to escape again, the drift current flowing through the first NMOS transistor MN1 should flow for a considerable amount of time. However, the low conversion gain operation and the high conversion gain operation should be performed in a timely manner for image output, and the comparator COMP operating in the presence of the trapped charge may cause random telegraph noise of the output image. The above-described phenomenon similarly occurs in the second NMOS transistor MN2.

However, when the power supply voltage VDD is provided to the first NMOS transistor MN1 at an appropriate timing through the first multiplexer MUX1, the value of the gate-source voltage of the first NMOS transistor MN1 becomes smaller than the value of the threshold voltage, and thus no channel is formed in the first NMOS transistor MN1. Thus, since the charge trap described above may be reduced or prevented, the random telegraph noise of the output image can be reduced or eliminated.

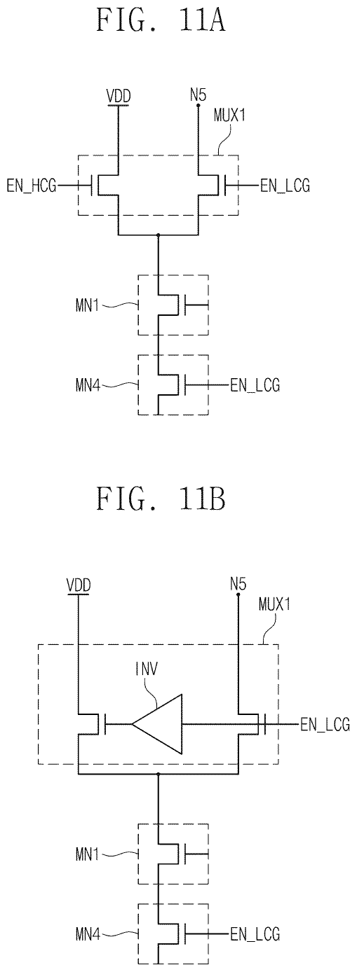

FIGS. 11A and 11B illustrate an example configuration of the multiplexer shown in FIG. 9. Although the first multiplexer MUX1 is shown as an example, the second multiplexer MUX2 will also have substantially the same configuration.

Referring first to FIG. 11A, the first multiplexer MUX1 may include NMOS transistors respectively turned on by the enable signal EN_HCG and the enable signal ENT_LCG. Since the enable signals EN_HCG and EN_LCG have opposite phases, the first multiplexer MUX1 may be implemented with two NMOS transistors. However, the configuration of the multiplexer is not limited thereto. For example, by adding the inverter INV as shown in FIG. 11B, it is possible to implement a multiplexer operated by one enable signal (e.g., EN_LCG). However, the configuration of the multiplexer is not limited thereto, and various modified configurations may be adopted.

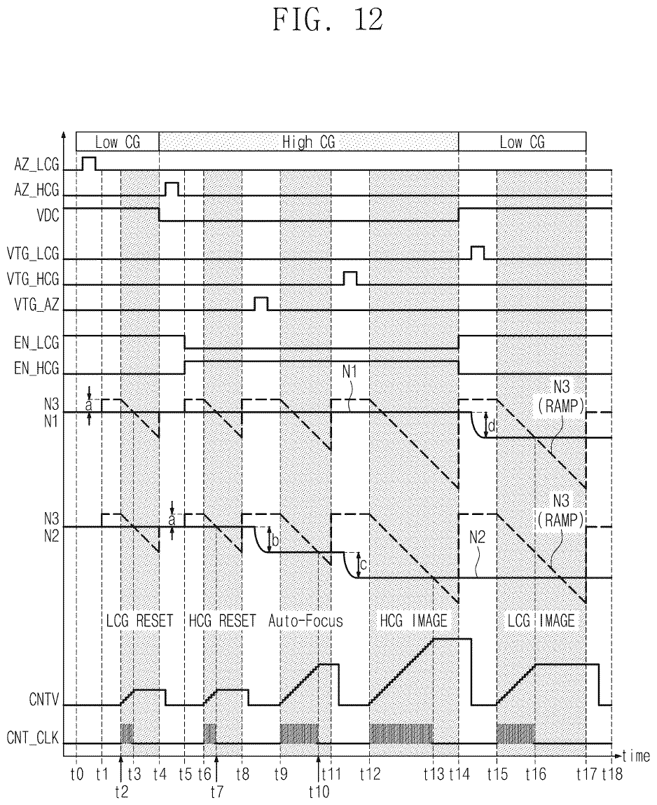

FIG. 12 is a timing diagram related to the operation of the comparator COMP of FIG. 1.

The timing diagram of FIG. 12 may be related to performing auto-focusing using a difference between an image signal output from some of the pixels belonging to one pixel group and an image signal output form all, or one or more, the pixels belonging to the one pixel group. That is, the timing diagram of FIG. 10 may be a timing diagram related to the operation of the pixel array shown in FIGS. 6 to 8.

Referring to FIG. 12, the time period from t0 to t4 is defined as a reset period in the low conversion operation. The time period from t0 to t4 may include an auto-zeroing section (e.g., t0 to t1) before the low conversion gain operation and a period for outputting a low conversion gain reset signal (hereinafter, referred to as an LCG reset signal) (e.g., t1 to t4).

The time period from t4 to t8 is defined as a reset period in the high conversion gain operation. The time period from t4 to t8 may include an auto-zeroing section (e.g., t4 to t5) after outputting the LCG signal, and a period for outputting a high conversion gain reset signal (hereinafter, referred to as an HCG reset signal) (e.g., t5 to t8).

The time period from t8 to t14 is defined as a period for outputting the image signal in the high conversion gain operation. The time period from t8 to t14 may be performed in two steps, and may include a period in which a high-conversion gain image signal (hereinafter, referred to as an HCG image signal) for auto-focusing is output in the time period from t8 to t11, and a period in which the full HCG image signals are output in the time period from t11 to t14.

The time period from t14 to t17 may include a period for outputting a low conversion gain image signal (hereinafter, referred to as the LCG image signal).

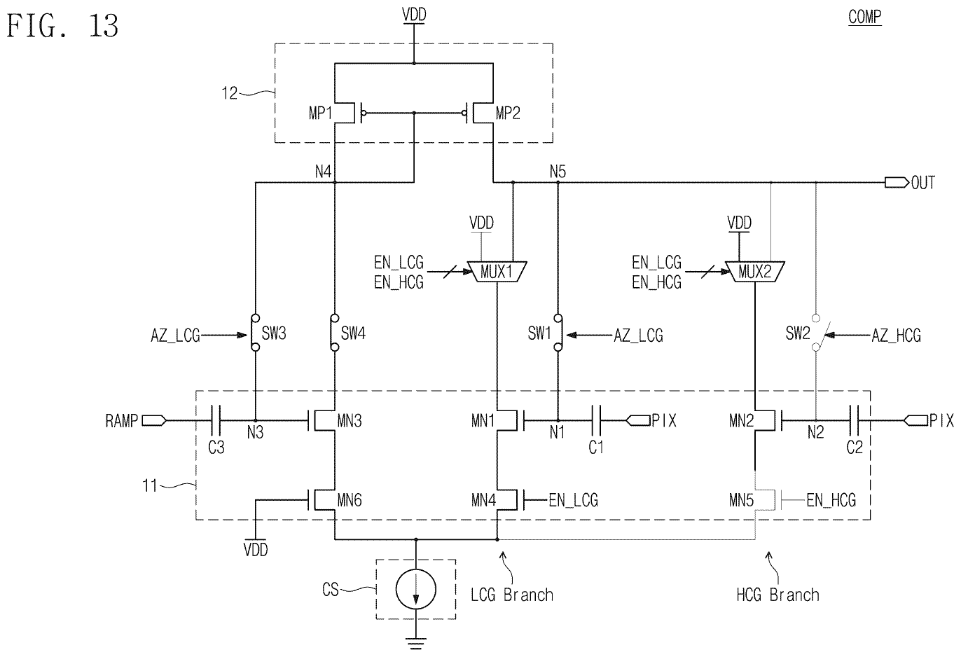

As an example, in FIG. 12, the image sensor is shown to operate in the order of the output of the LCG reset signal, the output of the HCG reset signal, an output of an HCG image signal, and an output of an LCG image signal. However, it is not limited thereto, and the image sensor may process the output of the LCG reset signal, the output of the HCG reset signal, an output of an HCG image signal, and an output of the LCG image signal according to various orders that may be combined. Hereinafter, the operation of the comparator will be described in detail with reference to FIGS. 13 to 17.

FIG. 13 illustrates operation of a comparator associated with auto-zeroing performed prior to a low conversion gain operation.

First, referring to FIG. 13 together with FIG. 1 and FIG. 12, in the time period from t0 to t4, the dual conversion gain transistor (e.g., DCT in FIG. 4) may be turned on by the gate voltage (e.g., VDCT in FIG. 4), and the capacitance of the floating diffusion node FD1 may be extended to the sum of CFD1 and CFD2. Then, ADC initialization (e.g., offset cancellation) may be performed.

In the time period from t0 to t1, the enable signal EN_LCG may be activated, and the enable signal ENT_HCG may be deactivated. As a result, the first multiplexer MUX1 may connect one end of the first NMOS transistor MN1 to the fifth node N5. The second multiplexer MUX2 may connect one end of the second NMOS transistor MN2 to the power supply voltage VDD.

In at least part of the time period from t0 to t1, the auto zero signal AZ_LCG may be activated. In response to the auto zero signal AZ_LCG, the third switch SW3 may connect the third node N3 and the fourth node N4, and the first switch SW1 may connect the first node N1 and the fifth node N5. As a result, the voltage levels of the input end and the output end of the comparator COMP become equal to each other so that the comparator COMP can be initialized.

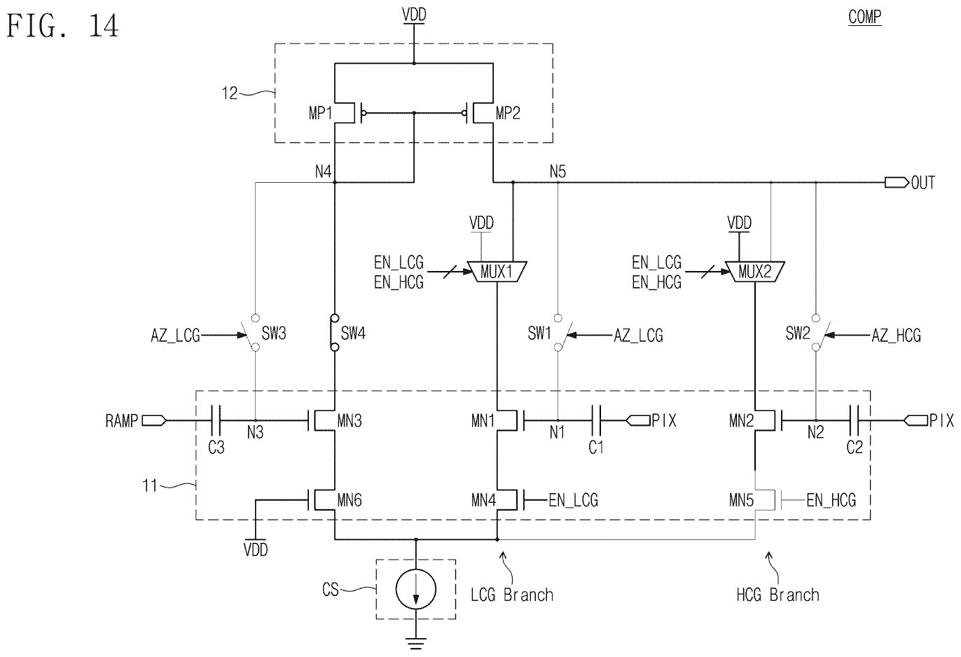

FIG. 14 illustrates the operation of a comparator associated with outputting a low conversion gain reset signal.

Referring to FIG. 14 together with FIG. 1 and FIG. 12, between t0 and t1, after auto-zeroing is completed, the auto zero signal AZ_LCG may be deactivated and the switches SW1 and SW3 may be switched off.

At time point t1, an offset ‘a’ may be applied to the ramp signal RAMP to convert the reset component of the pixel signal PIX into a digital signal, and the level of the ramp signal RMP may decrease from time point t2. The counter CNT may count the counting clock signal CNT_CLK from time point t2 to time point t3 when the polarity of the output OUT of the comparator COMP changes. The counting value CNTV in the time period from t2 to t3 may correspond to the value of the LCG reset signal.

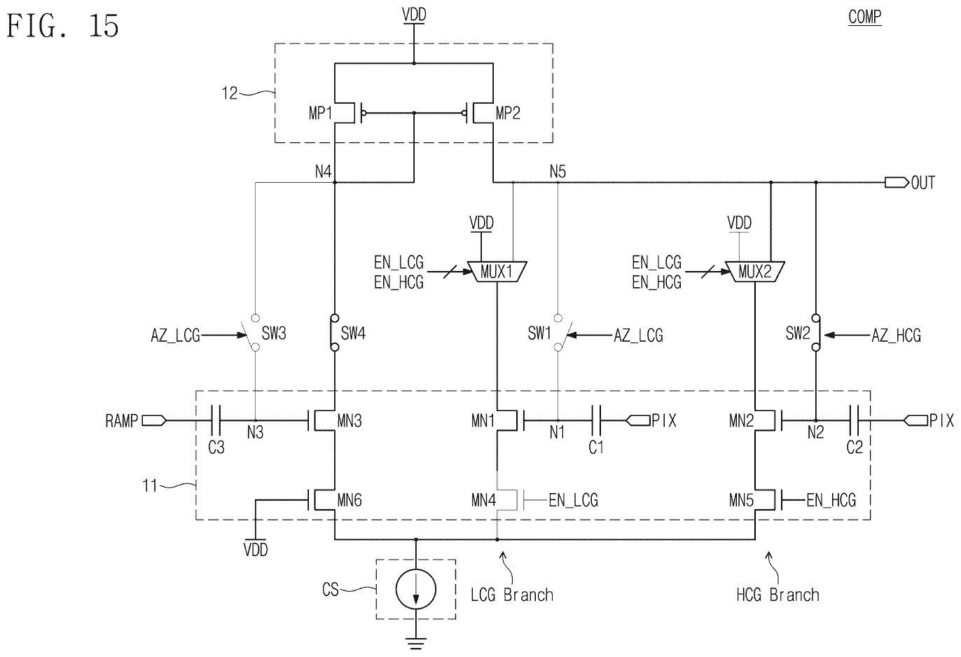

FIG. 15 shows the operation of the comparator associated with auto-zeroing performed after the output of the low conversion gain reset signal.

Referring to FIG. 15 together with FIG. 1 and FIG. 12, in the time period from t4 to t14, the gate voltage (e.g., VDCT in FIG. 4)is deactivated so that the dual conversion gain transistor (e.g., DCT in FIG. 4) may be turned off, and the capacitance of the floating diffusion node FD1 may decrease to CFD1. The image sensor may perform a high conversion gain operation.

In the time period from t4 to t5, signals for performing auto-zeroing in the HCG may be applied to the comparator COMP. For example, the deactivated enable signal EN_LCG may be applied to the fourth NMOS transistor MN4 and the first multiplexer MUX1, and the activated enable signal EN_HCG may be applied the fifth NMOS transistor MN5 and the second multiplexer MUX2.

In the case of the LCG branch, the first multiplexer MUX1 may connect one end of the first NMOS transistor MN1 to the power supply voltage VDD in response to the activated enable signal EN_HCG and/or the deactivated enable signal EN_LCH. The fourth NMOS transistor MN4 is turned off by the deactivated enable signal EN_LCG so that the other end of the first NMOS transistor MN1 may be cut off from the current source CS.

A voltage by the pixel signal PIX is applied to the gate electrode of the first NMOS transistor MN1 so that the first NMOS transistor MN1 is still turned on. Since the power supply voltage VDD is input to the drain electrode of the NMOS transistor MN1 in a state in which the fourth NMOS transistors MN4 are turned off (e.g., cut off) by the enable signal EN_LCG, the potential of the source electrode of the first NMOS transistor MN1 may converge to the power supply voltage VDD. Since the pixel signal PIX input to the gate electrode of the first NMOS transistor MN1 is smaller than the power supply voltage VDD, the gate-source voltage Vgs of the first NMOS transistor MN1 is smaller than the threshold voltage Vth. Therefore, since no channel is formed in the first NMOS transistor MN1, charges of the channel are not trapped at the interface, and as a result, a possibility that an operational error of the comparator COMP occurs may be reduced, or blocked.

In the case of the HCG branch, the second multiplexer MUX2 may connect one end of the second NMOS transistor MN2 to the fifth node N5 in response to the activated enable signal EN_HCG and/or the deactivated enable signal EN_LCH. The fifth NMOS transistor MN5 is turned on by the activated enable signal EN_HCG so that the other end of the second NMOS transistor MN2 may be connected to the current source CS.

In at least part of the time period from t4 to t5, the auto-zero signal AZ_HCG may be activated, and the comparator COMP may be initialized in response to the auto-zero signal AZ_HCG. For example, the voltage levels of the input terminals and/or the output terminals of the comparator COMP are equal to each other so that the comparator COMP can be initialized.

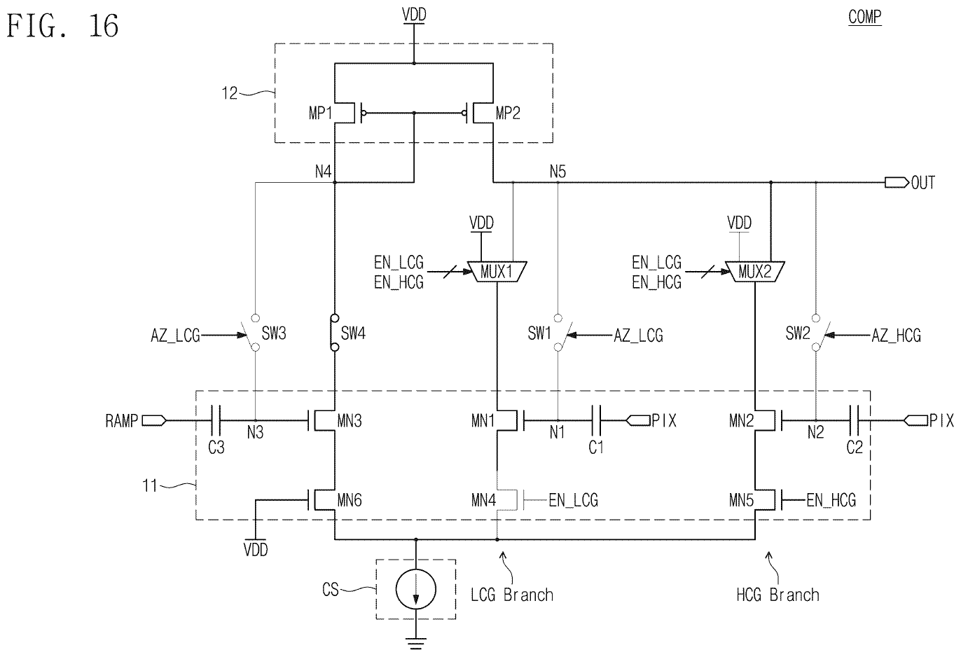

FIG. 16 shows the operation of the comparator associated with the output of the high conversion gain reset signal and the output of a high conversion gain image signal.

Referring to FIG. 16 together with FIGS. 1 and 12, at the time point t5, an offset may be applied to the ramp signal RAMP to convert a reset component of the pixel signal PIX input to the comparator COMP into a digital signal, and the level of the ramp signal RMP may decrease from the time point t6. The counter CNT may count the counting clock signal CNT_CLK from the time point t6 to the time point t7 when the polarity of the output OUT of the comparator COMP changes. The counting value CNTV in the time period from t6 to t7 may correspond to the value of the HCG reset signal.

An HCG image signal for auto-focusing may be output in the time period from t8 to t11. The HCG image signal for auto-focusing may be obtained by comparing the pixel signal PIX obtained by turning on some of the transfer transistors of the pixel with the ramp signal RAMP. For example, the gate voltage for turning on some of the transfer transistors of a pixel is shown in FIG. 12 as VTG_AZ, which will be understood as the voltage for turning on any two transistors of TG1 to TG4 of FIG. 2.

At some time point between t8 and t9, some of the transfer transistors of the pixel may be turned on. As a result, the voltage level of the second node N2 may be reduced, as indicated by ‘b’ in FIG. 12 by the charges accumulated in the floating diffusion node. Since only some of the transfer transistors TG1 to TG4 of the pixel have been turned on, the amount of decrease indicated by ‘b’ will be less than the amount of decrease when all, or one or more, of the transfer transistor TG1 to TG4 have been turned on. At some time point between t8 and t9, all, or one or more, of the transfer transistors of the pixel may be turned off.

At time point t9, the level of the ramp signal RAMP may decrease. The counter CNT may count the counting clock signal CNT_CLK from the time point t9 to the time point t10 when the polarity of the output OUT of the comparator COMP changes. The counting value CNTV in the time period from t9 to t10 may correspond to the value of the HCG image signal for auto-focus.

In the time period from t11 to t14, a full HCG image signal may be output. The entire HCG image signal may be obtained by comparing the pixel signal PIX obtained by turning on all, or one or more, of the transmission transistors of the pixel with the ramp signal RAMP. For example, the gate voltage for obtaining the full HCG image signal is shown in FIG. 12 as VTG_HCG.

At some time point between t11 and t12, all, or one or more, of the remaining transistors of the transmission transistors of the pixel that are not turned on may be turned on. As a result, the voltage level of the second node N2 may decrease, as indicated by ‘c’ in FIG. 12, due to the charges accumulated in the floating diffusion node. At some time point between t11 and t12, all, or one or more, of the transfer transistors of the pixel may be turned off.

At time point t12, the level of the ramp signal RAMP may decrease. The counter CNT may count the counting clock signal CNT_CLK from the time point t12 to the time point t13 when the polarity of the output OUT of the comparator COMP changes. The counting value CNTV in the time period from t12 to t13 may correspond to the value of the entire HCG image signal.

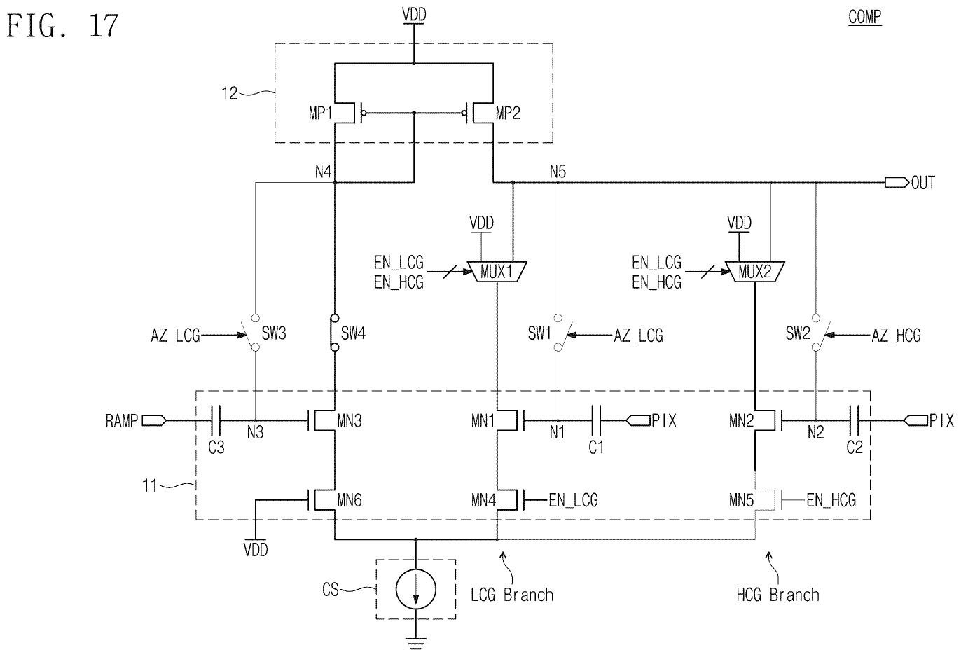

FIG. 17 illustrates the operation of a comparator associated with a low conversion gain image signal.

Referring to FIG. 17 together with FIG. 1 and FIG. 12, in the time period from t14 to t17, the gate voltage (e.g., VDCT in FIG. 4) may be activated so that the dual conversion gain transistor (e.g., DCT in FIG. 4) may be turned on, and the capacitance of the floating diffusion node FD1 may increase again by the sum of CFD1 and CFD2. The image sensor may perform a low conversion gain operation.

In the case of the LCG branch, the first multiplexer MUX1 may connect one end of the first NMOS transistor MN1 to the fifth node N5 in response to the deactivated enable signal EN_HCG and/or the activated enabling signal EN_LCH. The fourth NMOS transistor MN4 is turned on by the activated enable signal EN_LCG so that the other end of the first NMOS transistor MN1 may be connected to the current source CS.

At some time point between t14 and t15, all, or one or more, of the transfer transistors of the pixel may be turned on. As a result, the voltage level of the second node N2 may be reduced, as indicated by ‘d’ in FIG. 12, by the charges accumulated in the floating diffusion node. At some time point between t14 and t15, all, or one or more, of the transfer transistors of the pixel may be turned off.

At time point t15, the level of the ramp signal RAMP may decrease. The counter CNT may count the counting clock signal CNT_CLK from the time point t15 to the time point t16 when the polarity of the output OUT of the comparator COMP changes. The counting value CNTV in the time period from t15 to t16 may correspond to the value of the LCG image signal.

In the case of the HCG branch, the second multiplexer MUX2 may connect one end of the second NMOS transistor MN2 to the power supply voltage VDD in response to the deactivated enable signal EN_HCG and/or the activated enable signal EN_LCH. The fifth NMOS transistor MN5 is turned off by the deactivated enable signal EN_HCG so that the other end of the second NMOS transistor MN2 may be cut off from the current source CS. As the power supply voltage VDD is applied to one end of the second NMOS transistor MN2, the charge of the channel may be reduced or prevented from being trapped to the interface, and as a result, the possibility of an operation error occurring is reduced or blocked, which is the same as that described above with reference to FIG. 15.

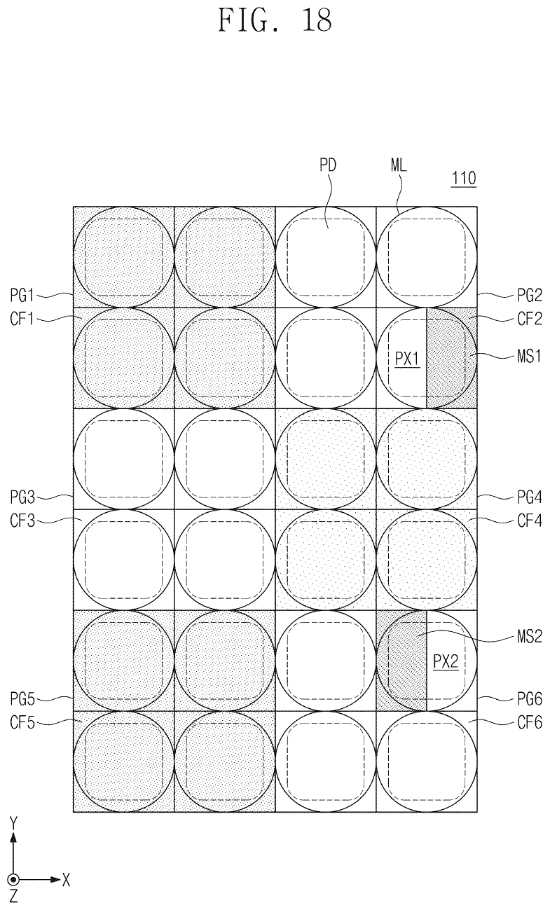

FIG. 18 shows a top view of the pixel array 110 of FIG. 1.

The pixel array 110 may include pixel groups PG1 to PG6. The pixel groups PG1 to PG6 may be repeatedly formed along the X-axis and the Y-axis. Each, or one or more, of the pixel groups PG1 to PG6 may include 2×2 pixels arranged along the X-axis and the Y-axis. Each, or one or more, pixel may include a photoelectric conversion element PD. Pixels included in one pixel group may share the same floating diffusion region with each other. As a result, pixel array 110 may have a tetra-bare pattern.

Color filters CF1 to CF4 for transmitting light of a specific wavelength band may be formed on the pixel groups PG1 to PG6, respectively. For example, color filters CF1 and/or CF5 may transmit red light, color filters FC2, CF3, and/or CF6 may transmit green light, and/or color filter CF4 may transmit blue light. However, the color filter CF4 may not be formed on the phase detection pixels PX1 and PX2, but example embodiments are limited thereto. Microlenses ML may be formed on each pixel.

The phase detection pixels PX1 and/or PX2 may have a different structure from other pixels (e.g., normal pixels) included in each pixel group. For example, the first pixel PX1 of the second pixel group PG2 may include a first metal shield MS1 that partially blocks light incident on the pixel. The sixth pixel PX6 of the sixth pixel group PG6 may include a second metal shield MS2 that partially blocks light incident on the pixel. With the above-described configuration, the phase information on the object may be obtained based on the pixel signals output from the phase detection pixels PX1 and/or PX2, and a phase detection auto-focus (hereinafter referred to as PDAF) may be executed.

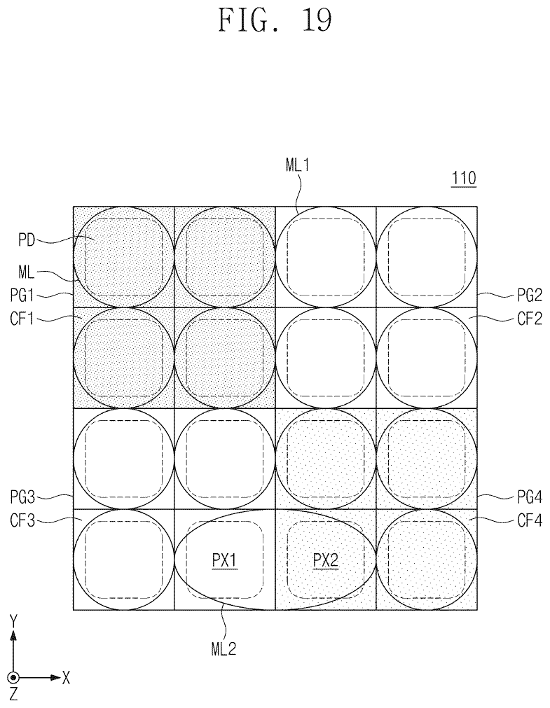

FIG. 19 shows a top view of the pixel array 110 of FIG. 1.

The pixel array 110 may include pixel groups PG1 to PG4. The arrangement of the pixels, the arrangement of the color filters, whether the pixels included in each pixel group are shared by the photoelectric conversion element, and the like are substantially the same as those described above with reference to FIG. 18, and thus a redundant description thereof will be omitted.

In some example embodiments, the first microlens ML1 may be formed on a normal pixel (e.g., a pixel excluding the phase detection pixels PX1 and PX2). A second microlens ML2 may be formed on two paired phase detection pixels (e.g., PX1 and PX2). For example, the second microlens ML2 may be formed on pixels (e.g., PX1) of the third pixel group PG3 associated with green light and pixels (e.g., PX2) of the fourth pixel group PG4 associated with blue light. With the above-described configuration, the phase information on the object may be obtained based on the pixel signals output from the phase detection pixels PX1 and/or PX2, and the PDAF may be executed.

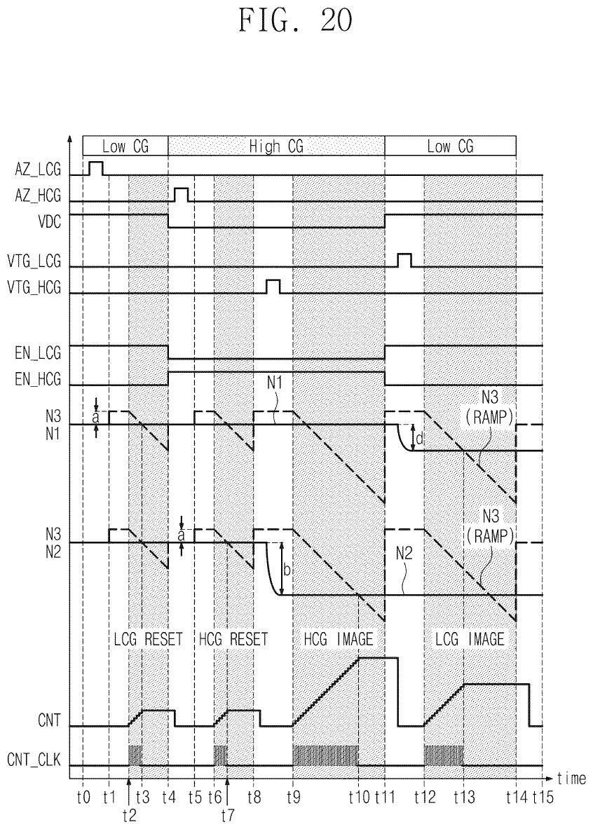

FIG. 20 is a timing diagram related to the operation of the comparator COMP of FIG. 1.

The timing diagram of FIG. 20 may relate to an image sensor that includes dedicated pixels that only perform auto-focus. That is, the timing diagram of FIG. 20 may be a timing diagram related to the operation of the pixel array shown in FIGS. 18 and/or 19.

Referring to FIG. 20, the time period from t0 to t4 is defined as a reset interval in the low conversion operation. The time period from t0 to t4 may include an auto-zeroing section (e.g., t0 to t1) before the low conversion gain operation and a time period for outputting a low conversion gain reset signal (hereinafter, referred to as the LCG reset signal) (e.g., t1 to t4).

The time period from t4 to t8 is defined as a reset period in the high conversion gain operation. The time period from t4 to t8 may include an auto-zeroing section (e.g., t4 to t5) after outputting the LCG signal, and a time period for outputting a high conversion gain reset signal (hereinafter, referred to as an HCG reset signal) (e.g., t5 to t8).

The time period from t8 to t11 is defined as a time period for outputting the image signal in the high conversion gain operation. Unlike FIGS. 11A and 11B and some example embodiments described with reference thereto, the time period from t8 to t11 may include only a time period in which a full HCG image signal is output. That is, the time period from t8 to t11 may not be related to auto-focusing.

The time period from t11 to t14 may include a time period for outputting a low conversion gain image signal (hereinafter, referred to as an LCG image signal).

As described above, example embodiments shown in FIG. 20 are substantially similar to that of FIG. 12, except that the time period from t8 to t11 is not related to auto-focusing. Therefore, the detailed description will be omitted.

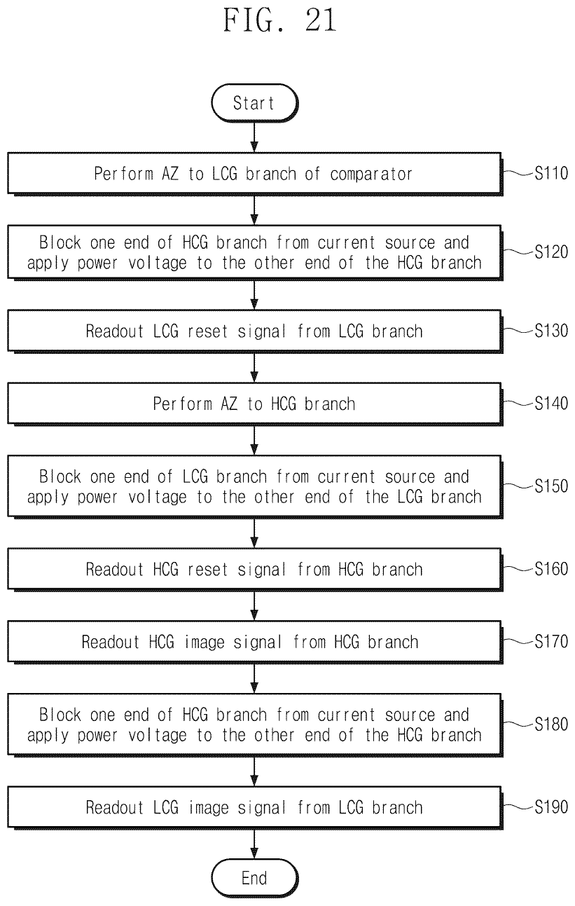

FIG. 21 is a flowchart illustrating a method of operating an analog-to-digital converter according to some example embodiments of the inventive concepts.

Referring to FIG. 21 together with FIGS. 12-17, in step S110, auto-zeroing AZ may be performed in a reference branch and an LCG branch of a comparator COMP. The auto-zeroing AZ may be performed by connecting the node N3 to which the ramp signal RAMP is input with the node N4, and by connecting the node N1 to which the pixel signal PIX is input with the nodes N5 (referring FIG. 13).

In step S120, one end (e.g., a source electrode) of an HCG branch of the comparator COMP may be cut off from the current source CS, and a power supply voltage VDD may be applied to the other end (e.g., a drain electrode) of the HCG branch. As a result, since no channel is formed in the transistor (e.g., MN2) of the HCG branch, the possibility that electrons in the channel are diffused to the interface and trapped maybe reduced or eliminated (referring FIG. 14).

In step S130, the LCG reset signal may be read from the LCG branch of the comparator COMP (referring FIG. 14). As the switches SW1 and SW3 are switched off, the comparator COMP may perform an LCG operation. The comparator COMP may compare the LCG reset signal with the ramp signal RAMP, output the comparison result as an output voltage OUT, and the counter may perform counting based on the output voltage OUT.

In step S140, auto-zeroing AZ may be performed at the HCG branch of the comparator COMP. Auto-zeroing AZ may be performed by connecting the node N2 to which the pixel signal PIX is input to the node N5 (referring FIG. 15).

In step S150, one end (e.g., a source electrode) of the LCG branch of the comparator COMP may be cut off from the current source CS, and a power supply voltage VDD may be applied to the other end (e.g., a drain electrode) of the LCG branch. As a result, since no channel is formed in the transistor (e.g., MN1) of the LCG branch, the possibility that electrons in the channel are diffused to the interface and trapped may be reduced or eliminated (referring FIG. 15).

In step S160, the HCG reset signal may be read from the HCG branch of the comparator COMP (referring FIG. 16). As the switch SW2 is switched off, the comparator COMP may perform an HCG operation. The comparator COMP may compare the HCG reset signal with the ramp signal RAMP, output the comparison result as an output voltage OUT, and the counter may perform counting based on the output voltage OUT.

In step S170, the HCG image signal may be read from the HCG branch of the comparator COMP. By the source follower transistor of the pixel, the capacitor C2 may be charged by a voltage potential (e.g., PIX) corresponding to the charges stored in the floating diffusion node, and the voltage of the pixel signal PIX may be reduced in two steps of ‘b’ and ‘c’ (referring FIG. 16). However, this is an operation of a pixel array in which all pixels perform auto-focusing, and in the case of a pixel array including pixels that only perform auto-focusing, the voltage of the pixel signal PIX may decrease in one step of ‘b’ (referring FIG. 20). The comparator COMP may compare the HCG image signal with the ramp signal RAMP, output the comparison result as an output voltage OUT, and the counter may perform counting based on the output voltage OUT.

In step S180, one end (e.g., a source electrode) of the HCG branch of the comparator COMP may be cut off from the current source CS, and a power supply voltage VDD may be applied to the other end (e.g., a drain electrode) of the HCG branch. As a result, since no channel is formed in the transistor (e.g., MN1) of the HCG branch, the possibility that electrons in the channel are diffused to the interface and trapped may be reduced or eliminated (referring FIG. 17).

In step S190, the LCG image signal may be read from the LCG branch of the comparator COMP (referring FIG. 17). By the source follower transistor of the pixel, the capacitor C1 may be charged by a voltage potential (e.g., PIX) corresponding to the charges stored in the floating diffusion node, and the voltage of the pixel signal PIX may be reduced by ‘d’. The comparator COMP may compare the LCG image signal with the ramp signal RAMP, output the comparison result as an output voltage OUT, and the counter may perform counting based on the output voltage OUT.

One or more of the elements disclosed above may include or be implemented in one or more processing circuitries such as hardware including logic circuits; a hardware/software combination such as a processor executing software; or a combination thereof. For example, the processing circuitries more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

According to some example embodiments, a method of operating an analog-to-digital converter includes performing a low conversion gain (LCG) auto-zeroing operation in a reference branch of a comparator and a LCG branch of the comparator, performing a LCG reset operation, performing a high conversion gain HCG auto auto-zeroing operation in the reference branch and a HCG branch of the comparator, performing a HCG reset operation, performing a HCG image operation, and performing a LCG image operation.

In some example embodiments, the performing the LCG auto-zeroing operation includes connecting a first drain electrode of a first NMOS transistor of the HCG branch to a power supply voltage source, disconnecting a second drain electrode of a second NMOS transistor of the LCG branch from the power supply voltage source, and connecting the second drain electrode to an output node of the comparator.

In some example embodiments, the performing the LCG auto-zeroing operation further includes disconnecting a first source electrode of the first NMOS transistor from a current source, and connecting a second source electrode of the second NMOS transistor to the current source.

In some example embodiments, the performing the HCG auto-zeroing operation includes disconnecting a first drain electrode of a first NMOS transistor of the HCG branch from a power supply voltage source, connecting the first drain electrode to an output node of the comparator, and connecting a second drain electrode of a second NMOS transistor of the LCG branch to the power supply voltage source.

In some example embodiments, the performing the HCG auto-zeroing operation further includes connecting a first source electrode of the first NMOS transistor to a current source, and disconnecting a second source electrode of the second NMOS transistor from the current source.

In some example embodiments, the performing the HCG image operation is performed by comparing, by the HCG branch, an image signal generated by all transistors of a pixel with a ramp signal and outputting a result of the comparison as an output signal and the performing the LCG image operation is performed by comparing, by the LCG branch, an image signal generated by less than all transistors of a pixel with the ramp signal and outputting a result of the comparison as the output signal.

In some example embodiments, during performance of the LCG image operation, a first drain electrode of a first NMOS transistor of the HCG branch is connected a power supply voltage source, a first source electrode of the first NMOS transistor is disconnected from a current source, a second drain electrode of a second NMOS transistor of the LCG branch is connected to an output node of the comparator, and a second source electrode of the second NMOS transistor is connected to the current source.

In some example embodiments, during performance of the HCG operation, the first drain electrode is connected to the output node, the first source electrode is connected to the current source, the second drain electrode is connected to the power supply voltage source, and the second source electrode is disconnected from the current source.

While the inventive concepts have been described with reference to some example embodiments thereof, it will be apparent to those of ordinary skill in the art that various changes and modifications may be made thereto without departing from the spirit and scope of the inventive concepts as set forth in the following claims.

What is claimed:

1. An analog-to-digital converter comprising:
an input stage including
a first NMOS transistor configured to receive a pixel signal through a first capacitor,
a second NMOS transistor configured to receive the pixel signal through a second capacitor, and
a third NMOS transistor configured to receive a ramp signal through a third capacitor;
an output stage including a first PMOS transistor and a second PMOS transistor connected in a current mirror structure, the first PMOS transistor configured to mirror a current flowing through the first NMOS transistor and to transmit the current to the second PMOS transistor;
a switching circuit including
a first switch between a first node and an output node of the output stage, the first node being between the first capacitor and the first NMOS transistor,
a second switch between a second node and the output node of the output stage, the second node being between the second capacitor and the second NMOS transistor, and
a third switch between a third node and a fourth node, the third node being between the third capacitor and the third NMOS transistor, and the fourth node being between the first PMOS transistor and the second PMOS transistor;
a current source configured to provide a bias current to the input stage,
a first multiplexer configured to connect a first end of the first NMOS transistor to the output node of the output stage or to a power supply voltage; and
a second multiplexer configured to connect a first end of the second NMOS transistor to the output node of the output stage or to the power supply voltage.

2. The analog-to-digital converter of claim 1, further comprising:
a fourth NMOS transistor between the first NMOS transistor and the current source; and
a fifth NMOS transistor between the second NMOS transistor and the current source.

3. The analog-to-digital converter of claim 2, further comprising:
a fourth switch between a first end of the third NMOS transistor and the fourth node.

4. The analog-to-digital converter of claim 3, further comprising:
a sixth NMOS transistor between a second end of the third NMOS transistor and the current source.

5. The analog-to-digital converter of claim 4, wherein the power supply voltage is connected to a gate electrode of the sixth NMOS transistor.

6. The analog-to-digital converter of claim 1, wherein the first switch and the third switch are configured to operate based on a first auto zero signal and the second switch is configured to operate based on a second auto zero signal.

7. The analog-to-digital converter of claim 6,
wherein the first NMOS transistor is configured to receive, as the pixel signal, a voltage corresponding to charges stored at a floating diffusion node of an image sensor via the first capacitor, and
wherein the second NMOS transistor is configured to receive, as the pixel signal, a voltage corresponding to charges stored at a floating diffusion node of the image sensor via the second capacitor.

8. The analog-to-digital converter of claim 1, wherein each of the first multiplexer and the second multiplexer includes at least two switches.

9. An analog-to-digital converter comprising:
a first PMOS transistor and a second PMOS transistor connected by a current mirror structure, a first end of the first PMOS transistor being connected to a first end of the second PMOS transistor by a power supply voltage;
a low conversion gain branch including a first NMOS transistor configured to receive a pixel signal through a first capacitor, and a first multiplexer configured to connect a first end of the first NMOS transistor to a second end of the second PMOS transistor or to the power supply voltage;
a high conversion gain branch including a second NMOS transistor configured to receive the pixel signal through a second capacitor, and a second multiplexer configured to connect a first end of the second NMOS transistor to the second end of the second PMOS transistor or to the power supply voltage;
a reference branch including a third NMOS transistor configured to receive a ramp signal through a third capacitor; and
a current source connected to the low conversion gain branch, the high conversion gain branch, and the reference branch.

10. The analog-to-digital converter of claim 9,
wherein the low conversion gain branch further includes a first switch between a first node and the second end of the second PMOS transistor, the first node being between the first capacitor and the first NMOS transistor,
wherein the high conversion gain branch further includes a second switch between a second node and the second end of the second PMOS transistor, the second node being between the second capacitor and the second NMOS transistor, and
wherein the reference branch further includes a third switch between a third node and a second end of the first PMOS transistor, the third node being between the third capacitor and the third NMOS transistor.

11. The analog-to-digital converter of claim 10, further comprising:
a fourth NMOS transistor between the first NMOS transistor and the current source;
and a fifth NMOS transistor between the second NMOS transistor and the current source.

12. The analog-to-digital converter of claim 11, further comprising:
a fourth switch between a first end of the third NMOS transistor and the second end of the first PMOS transistor.

13. The analog-to-digital converter of claim 12, further comprising:
a sixth NMOS transistor between a second end of the third NMOS transistor and the current source.

14. An image sensor comprising:
a pixel array including a plurality of pixel groups, a first pixel group of the plurality of pixel groups including a first plurality of pixels sharing a first floating diffusion node; and
an analog-to-digital converter configured to process a pixel signal output from the first plurality of pixels,
the analog-to-digital converter comprising:
an input stage including a first NMOS transistor configured to receive the pixel signal through a first capacitor, a second NMOS transistor configured to receive the pixel signal though a second capacitor, and a third NMOS transistor configured to receive a ramp signal through a third capacitor;
an output stage including a first PMOS transistor and a second PMOS transistor connected by a current mirror structure;
a current source configured to provide a bias current to the input stage;
a first multiplexer configured to connect a first end of the first NMOS transistor to an output node of the output stage or to a power supply voltage; and
a second multiplexer configured to connect a first end of the second NMOS transistor to the output node of the output stage or to the power supply voltage.

15. The image sensor of claim 14, wherein the analog-to-digital converter includes a switching circuit, the switching circuit further comprising:
a first switch between a first node and an output node of the output stage, the first node being between the first capacitor and the first NMOS transistor;
a second switch between a second node and the output node of the output stage, the second node being between the second capacitor and the second NMOS transistor; and
a third switch between a third node and a fourth node, the third node being between the third capacitor and the third NMOS transistor, and the fourth node being between the first PMOS transistor and the second PMOS transistor.

16. The image sensor of claim 15, further comprising:
a counter configured to count a signal output from the output stage.

17. The image sensor of claim 16, wherein the first plurality of pixels includes:
a plurality of photoelectric conversion elements;
a plurality of transfer transistors, each transfer transistor of the plurality of transfer transistors having a first end connected to a corresponding photoelectric conversion element and a second end connected to the first floating diffusion node;
a reset transistor connected to the first floating diffusion node;
a dual conversion gain transistor connected to the first floating diffusion node and the reset transistor;
a source follower transistor configured to generate the pixel signal corresponding to a voltage of the first floating diffusion node; and
a selection transistor connected to the source follower transistor, the selection transistor configured to output the pixel signal to a column line.

18. The image sensor of claim 14, further comprising:
a fourth NMOS transistor between the first NMOS transistor and the current source; and
a fifth NMOS transistor between the second NMOS transistor and the current source.

19. The image sensor of claim 18, further comprising:
a fourth switch between a first end of the third NMOS transistor and a fourth node.

20. The image sensor of claim 19, further comprising:
a sixth NMOS transistor between a second end of the third NMOS transistor and the current source.
